(19) United States
(12) Patent Application Publication
(10) Pub. No.: US 2022/0163642 A1
(43) Pub. Date: May 26, 2022

(54) CURRENT GENERATION CIRCUIT AND RANGING SYSTEM

(71) Applicant: C/O SONY SEMICONDUCTOR SOLUTIONS CORPORATION, KANAGAWA (JP)

(72) Inventor: HAYATO KAMIZURU, KANAGAWA (JP)

(21) Appl. No.: 17/436,881

(22) PCT Filed: Feb. 18, 2020
(86) PCT No.: PCT/JP2020/006183

§ 371 Date: Sep. 7, 2021

(30) Foreign Application Priority Data
Mar. 18, 2019 (JP) 2019-050269

(51) Int. Cl. G01S 7/4865; G01S 17/10

(52) U.S. Cl. CPC G01S 7/4865; G01S 17/10

(57) ABSTRACT

A current generation circuit according to the present disclosure includes a constant current source (10), a current mirror circuit (20), and a gate length adjusting unit (9). The constant current source (10) is able to flow a reference current (Id) with a plurality of values. The current mirror circuit (20) is constituted by a first transistor (40) that is connected to the constant current source (10) and second transistors (50) that are connected to respective single photon avalanche diode (SPAD) elements (6a). The gate length adjusting unit (9) adjusts, on the basis of the reference current (Id) that is set in the constant current source (10), a gate length of the first transistor (40) and a gate length of each of the second transistors (50).

### FIELD

The present disclosure relates to a current generation circuit and a ranging system.

### BACKGROUND

There is a known ranging method called a direct time of flight (ToF) technique as one of ranging techniques for measuring a distance to an object to be measured by using light. In the direct ToF technique, a distance to an object is measured on the basis of a time period between a time point at which light is emitted from a light source and a time point at which the light is received by a light receiving element as reflected light that is reflected by an object to be measured (for example, see Patent Literature 1).

### CITATION LIST

### Patent Literature

Patent Literature 1: Japanese Laid-open Patent Publication No. 2014-081254

### SUMMARY

### Technical Problem

However, in the conventional technology described above, if a plurality of photons are incident on single photon avalanche diode (SPAD) elements that are used as a light receiving element in a short time, the dead time of the SPAD elements may possibly vary. Furthermore, the dynamic range of a ranging system may possibly be reduced due to variations in the dead time of the SPAD elements.

Accordingly, in the present disclosure, a current generation circuit and a ranging system capable of expanding the dynamic range are proposed.

### Solution to Problem

According to the present disclosure, there is provided a current generation circuit. The current generation circuit includes a constant current source, a current mirror circuit, and a gate length adjusting unit. The constant current source is able to flow a reference current with a plurality of values. The current mirror circuit is constituted by a first transistor that is connected to the constant current source and second transistors that are connected to respective single photon avalanche diode (SPAD) elements. The gate length adjusting unit adjusts, on the basis of the reference current that is set in the constant current source, a gate length of the first transistor and a gate length of each of the second transistors.

### Advantageous Effects of Invention

According to the present disclosure, it is possible to expand the dynamic range. Furthermore, the effects described here are not always limited and any one of the effects described in the present disclosure may be achieved.

### BRIEF DESCRIPTION OF DRAWINGS

FIG. 1 is a diagram schematically illustrating ranging performed by using a direct ToF technique applicable to an embodiment of the present disclosure.

FIG. 2 is an example of a histogram based on a time point at which a light receiving unit, which is applicable to the embodiment of the present disclosure, receives light.

FIG. 3 is a block diagram illustrating a configuration example of a ranging apparatus according to the embodiment of the present disclosure.

FIG. 4 is a schematic diagram illustrating a configuration example of a device applicable to a light receiving unit according to the embodiment of the present disclosure.

FIG. 5 is a circuit diagram illustrating a configuration example of a pulse output unit according to the embodiment of the present disclosure.

FIG. 6 is a diagram illustrating a relationship between a gate voltage and a reference current in the pulse output unit according to the present disclosure.

FIG. 7 is a diagram illustrating, by using a timing chart, an operation of the pulse output unit in a reference example in the present disclosure.

FIG. 8 is a diagram illustrating an adjusting process performed by a gate length adjusting unit according to the embodiment of the present disclosure.

FIG. 9 is a diagram illustrating, by using a timing chart, an operation of the pulse output unit according to the embodiment of the present disclosure.

### DESCRIPTION OF EMBODIMENTS

Preferred embodiments of the present disclosure will be described in detail below with reference to the accompanying drawings. Furthermore, in each of the embodiments, by assigning the same reference numerals to components having the same functional configuration, overlapping descriptions thereof will be omitted.

A ranging technique called a direct ToF technique is known as one of ranging techniques for measuring a distance to an object to be measured by using light. In the direct ToF technique, a distance to an object is measured on the basis of a time period between a time point at which light is emitted from a light source and a time point at which the light is received by a light receiving element as reflected light that is reflected by an object to be measured.

However, in the conventional technology described above, if a plurality of photons are incident on SPAD elements that are used as the light receiving element in a short time, the dead time of the SPAD elements sometimes varies. Furthermore, the dynamic range of a ranging system may possibly be reduced due to variations in the dead time of the SPAD elements.

This is because, if the dead time of the SPAD elements is increased, the maximum rate of the photons that can be detected by the SPAD elements is decreased.

Accordingly, it is expected to implement a current generation circuit and a ranging system capable of overcoming the problems described above and expanding the dynamic range are expected.

[Ranging Method]

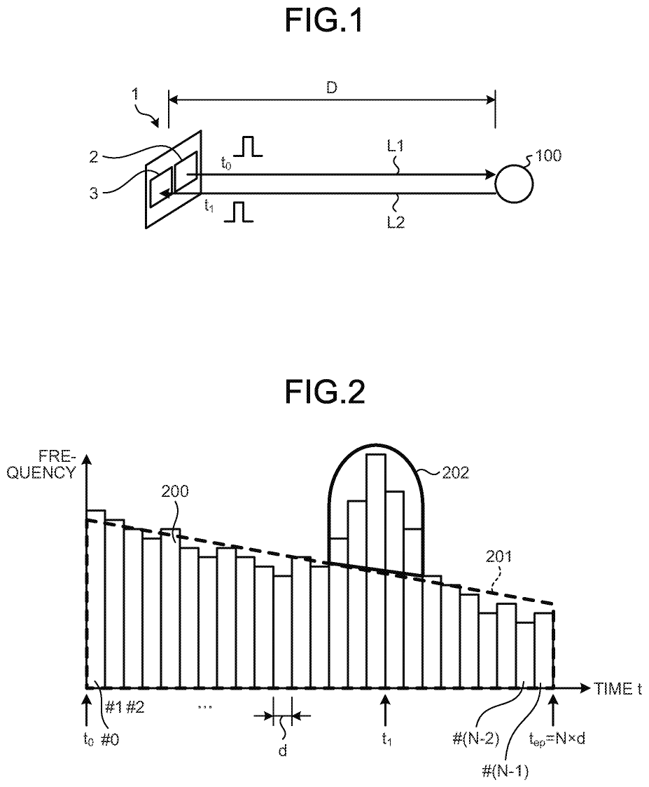

The present disclosure relates a technology for performing ranging by using light. Thus, in order to facilitate understanding an embodiment of the present disclosure, a ranging method applicable to the embodiment will be described with reference to FIG. 1 and FIG. 2.

FIG. 1 is a diagram schematically illustrating ranging performed by using the direct ToF technique that is applicable to the embodiment of the present disclosure. In the embodiment, the direct ToF technique is used as the ranging technique.

The direct ToF technique is a technique for performing ranging on the basis of a time difference between a light emission timing at which emission light L1 is emitted from a light source unit 2 and a light reception timing a time point at which reflected light L2 that is reflected by an object to be measured 100 is received by a light receiving unit 3.

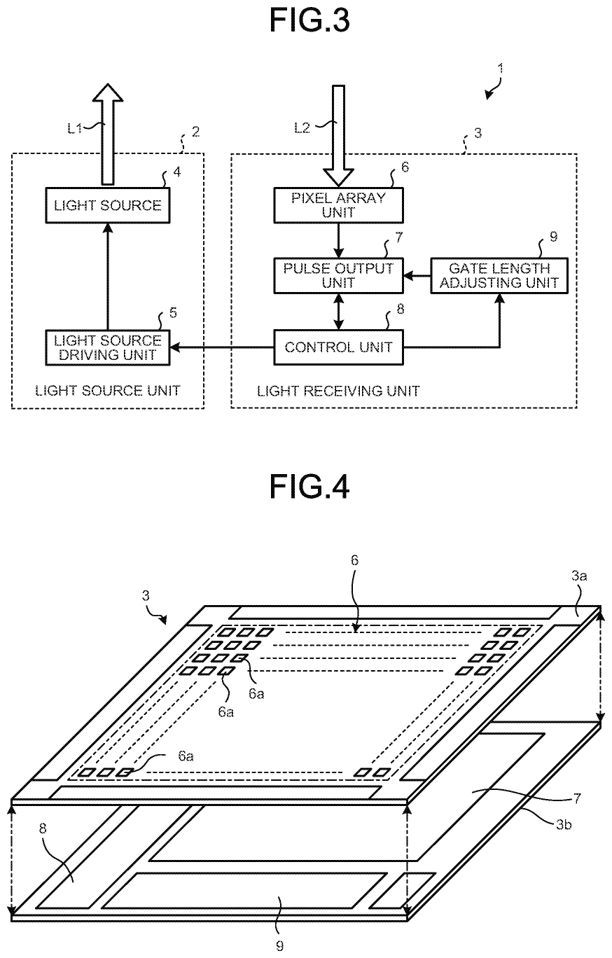

A ranging apparatus 1 includes the light source unit 2 and the light receiving unit 3. The ranging apparatus 1 is an example of the ranging system. The light source unit 2 includes a light source 4 that is, for example, a laser diode (see FIG. 3) and is driven so as to emit pulsed laser light.

The emission light L1 that is emitted from the light source unit 2 is reflected by the object to be measured 100 and is received by the light receiving unit 3 as the reflected light L2. The light receiving unit 3 includes a pixel array unit 6 (see FIG. 3) that converts the light to an electrical signal by performing photoelectric conversion, and then, outputs a signal in accordance with the received light.

Here, it is assumed that a time point (light emission timing) at which the light source unit 2 emits light is denoted by time to, and a time point (light reception timing) at which the light receiving unit 3 receives reflected light L2 that is obtained from the emission light L1 that is emitted from the light source unit 2 and that is reflected by the object to be measured 100 is denoted by time t₁.

If a constant c is a speed of light (2.9979×10⁸ [m/sec]), a distance D between the ranging apparatus 1 and the object to be measured 100 is calculated by Equation (1) as below.

D=(c/2)×(t₁−t₀) (1)

Furthermore, it is preferable that the ranging apparatus 1 repeatedly perform the process described above several times. Moreover, the light receiving unit 3 may include a plurality of SPAD elements 6a (see FIG. 4) and calculate each of the distances D on the basis of the respective light reception timings at each of which the reflected light L2 is received by each of the SPAD elements 6a.

The ranging apparatus 1 generates a histogram by classifying, on the basis of categories (bins), time period between time to, which is light emission timing, and time tₘ (hereinafter, also referred to as “light receiving time tₘ”), which is the light reception timing at which the light is received by the light receiving unit 3.

FIG. 2 is a diagram illustrating an example of a histogram based on a time point at which the light receiving unit 3, which is applicable to the embodiment of the present disclosure, receives light. In FIG. 2, the horizontal axis indicates bins and the vertical axis indicates the frequency for each bin. The bins are obtained by classifying the light receiving time tₘ per predetermined unit time d.

Specifically, a bin #0 corresponds to 0≤tₘ<d, a bin #1 corresponds to d≤tₘ<2×d, a bin #2 corresponds to 2×d≤tₘ<3×d, . . . , and a bin #(N−2) corresponds to (N−2)×d≤tₘ<(N−1)×d. If exposure time of the light receiving unit 3 is denoted by time tₑₚ, tₑₚ=N×d holds.

The ranging apparatus 1 counts the number of acquisitions of the light receiving time tₘ on the basis of the bins, obtains a frequency 200 for each bin, and generates a histogram. Here, the light receiving unit 3 also receives light other than the reflected light L2 that is reflected of the emission light L1 emitted from the light source unit 2.

For example, an example of the light other than the target reflected light L2 includes ambient light around the ranging apparatus 1. The ambient light is light that is randomly incident on the light receiving unit 3 and an ambient light component 201 due to the ambient light in the histogram causes noise with respect to the target reflected light L2.

In contrast, the reflected light L2 to be targeted is the light that is received in accordance with a specific distance and appears as an active light component 202 in the histogram. The bins associated with the peak of the frequency in the active light component 202 are the bins corresponding to the distance D of the object to be measured 100.

The ranging apparatus 1 acquires representative time of the subject bins (for example, the time at the center of the bins) as the time t₁, so that the ranging apparatus 1 is able to calculate the distance D to the object to be measured 100 in accordance with Equation (1). In this way, by using a plurality of light receiving results, it is possible to perform appropriate ranging with respect to random noise.

[Configuration of Ranging Apparatus]

In the following, a configuration of the ranging apparatus 1 according to the embodiment will be described with reference to FIG. 3 and FIG. 4. FIG. 3 is a block diagram illustrating a configuration example of the ranging apparatus 1 according to the embodiment of the present disclosure. As described above, the ranging apparatus 1 includes the light source unit 2 and the light receiving unit 3.

The light source unit 2 includes the light source 4 and a light source driving unit 5. The light source 4 is constituted by, for example, a laser diode, such as a vertical cavity surface emitting laser (VCSEL). Furthermore, the light source 4 is not limited to the VCSEL and a laser diode array in which laser diodes are arranged in the form of a line may also be used.

The light source driving unit 5 drives the light source 4. The light source driving unit 5 drives the light source 4 on the basis of, for example, a light emission control signal that is output from a control unit 8 in the light receiving unit 3 such that the emission light L1 having a predetermined timing and a pulse width is emitted from the light source 4.

The light source driving unit 5 is able to drive the light source 4 so as to scan the laser light emitted from the light source 4, which has laser diodes arrayed in the form of line in a vertical direction relative to the line.

The light receiving unit 3 includes the pixel array unit 6, a pulse output unit 7, the control unit 8, and a gate length adjusting unit 9.

The pixel array unit 6 includes the plurality of SPAD elements 6a (see FIG. 4) that are two-dimensionally arrayed in a grid manner. In this type of the SPAD elements 6a, by applying a large reverse bias voltage that generates avalanche multiplication to a cathode, avalanche multiplication is generated in an internal portion caused by electrons that are generated in accordance with a single incident photon.

Namely, the SPAD element 6a has a characteristic in which a large amount of current flows in accordance with a single incident photon. Then, by using the characteristic of the SPAD element 6a, the SPAD element 6a is able to detect a single incident photon included in the reflected light L2 with a high degree of sensitivity.

Operations of the plurality of the SPAD elements 6a performed in the pixel array unit 6 are controlled by the control unit 8. For example, the control unit 8 is able to control reading of a signal from each of the SPAD elements 6a for each block that includes (n×m) pieces of the SPAD elements 6a having n pixels in a row direction and m pixels in the column direction.

Furthermore, the control unit 8 scans each of the SPAD elements 6a in the column direction in units of blocks, and furthermore, scans each of the SPAD elements 6a in the column direction for each row, so that the control unit 8 is able to read a signal from each of the SPAD elements 6a.

Furthermore, in the embodiment, the control unit 8 may also individually read a signal from each of the SPAD elements 6a. The signal generated in each of the SPAD elements 6a included in the pixel array unit 6 is supplied to the pulse output unit 7.

The pulse output unit 7 outputs a predetermined pulse signal as a digital signal to the control unit 8 in accordance with the signal generated in each of the SPAD elements 6a. The pulse output unit 7 will be described in detail later.

The control unit 8 performs overall control of the ranging apparatus 1 in accordance with, for example, the program that is installed in advance. For example, the control unit 8 controls the light emission timing of the light source 4 by controlling the light source driving unit 5.

Furthermore, the control unit 8 generates a histogram illustrated in FIG. 2 on the basis of the pulse signal that is output from the pulse output unit 7. Furthermore, the control unit 8 performs predetermined arithmetic processing on the basis of the data on the generated histogram, and calculates the distance D to the object to be measured 100.

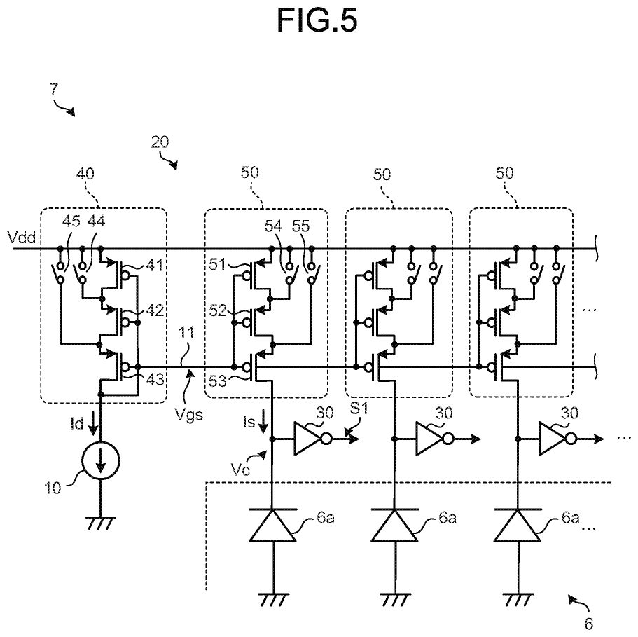

Furthermore, the control unit 8 sets, in accordance with an external environment or the like, a current (hereinafter, also referred to as a reference current Id (see FIG. 5)) flowing in a constant current source 10 (see FIG. 5) included in the pulse output unit 7. For example, the control unit 8 changes the reference current Id to an optimum value if a temperature around the ranging apparatus 1 is changed, if an external power supply is changed, or the like.

The gate length adjusting unit 9 adjusts a gate length of a first transistor 40 (see FIG. 5) and a gate length of second transistors 50 (see FIG. 5) that are included in the pulse output unit 7 on the basis of the reference current Id that is set by the control unit 8. The gate length adjusting unit 9 will be described in detail later.

FIG. 4 is a schematic diagram illustrating a configuration example of a device applicable to the light receiving unit 3 according to the embodiment of the present disclosure. In FIG. 4, the light receiving unit 3 is configured such that a light receiving chip 3a and a logic chip 3b, each of which is constituted by a semiconductor chip, are laminated. Furthermore, in FIG. 4, in order to facilitate understanding, the light receiving chip 3a and the logic chip 3b are illustrated in a separate state.

On the light receiving chip 3a, the SPAD elements 6a are arrayed in the area of the pixel array unit 6 in a two-dimensional grid manner. On the logic chip 3b, the pulse output unit 7, the control unit 8, and the gate length adjusting unit 9 are provided. Furthermore, a configuration of each of the light receiving chip 3a and the logic chip 3b is not limited to the example illustrated in FIG. 4.

[Configuration and Operation of Pulse Output Unit]

In the following, a configuration and an operation of the pulse output unit 7 according to the embodiment will be described with reference to FIG. 5 to FIG. 9. FIG. 5 is a circuit diagram illustrating a configuration example of the pulse output unit 7 according to the embodiment of the present disclosure.

As illustrated in FIG. 5, the pulse output unit 7 includes the constant current source 10, a current mirror circuit 20, and a plurality of inverters 30. Furthermore, the current mirror circuit 20 includes the first transistor 40 and a plurality of the second transistors 50.

The constant current source 10 is provided between the first transistor 40 included in the current mirror circuit 20 and a ground potential. The constant current source 10 flows the reference current Id with a value that is set by the control unit 8 into the first transistor 40.

The first transistor 40 included in the current mirror circuit 20 is constituted such that three P-type transistors 41 to 43 are arranged in series in this order from the power supply voltage Vdd side. Furthermore, all of the gates of the P-type transistors 41 to 43 are connected to a gate wiring 11, so that the P-type transistors 41 to 43 are integrally operated as a single P-type transistor.

Namely, the first transistor 40 functions as a P-type transistor in which the gates are connected to the gate wiring 11.

The first transistor 40 is provided with, in addition to the P-type transistors 41 to 43, bypass switches 44 and 45. Each of the bypass switches 44 and 45 is constituted by a P-type transistor having the minimum size. Furthermore, in the present disclosure, the “P-type transistor having the minimum size” indicates a smallest sized P-type transistor that can be formed on the logic chip 3b.

The bypass switch 44 is provided between the power supply voltage Vdd and a source of the P-type transistor 42. Furthermore, by allowing the bypass switch 44 to be in a conduction state, the bypass switch 44 is able to bypass the P-type transistor 41 in the first transistor 40.

The bypass switch 45 is provided between the power supply voltage Vdd and a source of the P-type transistor 43. Furthermore, by allowing the bypass switch 45 to be in a conduction state, the bypass switch 44 is able to bypass the P-type transistors 41 and 42 in the first transistor 40.

Namely, in the embodiment, the gate length adjusting unit 9 controls the bypass switches 44 and 45, so that the gate length adjusting unit 9 is able to adjust the gate length of the first transistor 40.

For example, the gate length adjusting unit 9 allows the bypass switch 45 to be in the conduction state, so that the gate length adjusting unit 9 is able to allow the gate length of the first transistor 40 to be in a short state (hereinafter, also referred to as a “short state”).

Furthermore, the gate length adjusting unit 9 allows the bypass switches 44 and 45 to be in a disconnected state, so that the gate length adjusting unit 9 is able to allow the gate length of the first transistor 40 to be in a long state (hereinafter, also referred to as a “long state”).

Furthermore, the gate length adjusting unit 9 allows the bypass switch 44 to be in the conduction state, so that the gate length adjusting unit 9 is able to allow the gate length of the first transistor 40 to be in a state between the short state and the long state (hereinafter, also referred to as a “medium state”).

Each of the second transistors 50 included in the current mirror circuit 20 is constituted such that three P-type transistors 51 to 53 are arranged in series in this order from the power supply voltage Vdd side. Furthermore, all of the gates of the P-type transistors 51 to 53 are connected to the gate wiring 11, so that the P-type transistors 51 to 53 are integrally operated as a single P-type transistor.

Namely, each of the second transistors 50 functions as a P-type transistors in which the gates are connected to the gate wiring 11.

Each of the second transistors 50 is provided with, in addition to the P-type transistors 51 to 53, bypass switches 54 and 55. The bypass switches 54 and 55 are constituted by a P-type transistor having the minimum size.

The bypass switch 54 is provided between the power supply voltage Vdd and the source of the P-type transistor 52. Furthermore, by allowing the bypass switch 54 to be in a conduction state, the bypass switch 54 is able to bypass the P-type transistor 51 in each of the second transistors 50.

The bypass switch 55 is provided between the power supply voltage Vdd and the source of the P-type transistor 53. Furthermore, by allowing the bypass switch 55 to enter in a conduction state, the bypass switch 55 is able to bypass the P-type transistors 51 and 52 in each of the second transistors 50.

Namely, in the embodiment, the gate length adjusting unit 9 controls the bypass switches 54 and 55, so that the gate length adjusting unit 9 is able to adjust the gate length of each of the second transistors 50.

For example, the gate length adjusting unit 9 allows the bypass switch 55 to be in the conduction state, so that the gate length adjusting unit 9 is able to allow the gate length of each of the second transistors 50 to be in the short state. Furthermore, the gate length adjusting unit 9 allows the bypass switch 54 to be in the conduction state, so that the gate length adjusting unit 9 is able to allow the gate length of each of the second transistors 50 to be in a medium state.

Furthermore, the gate length adjusting unit 9 allows the bypass switches 54 and 55 to be in a disconnected state, the gate length adjusting unit 9 is able to allow the gate length of each of the second transistors 50 to be in a long state.

Furthermore, all of the sources of the first transistor 40 and the sources of the plurality of the second transistors 50 are connected to the power supply voltage Vdd. Furthermore, the gates of the first transistor 40 are connected to a drain of the first transistor 40.

Consequently, the first transistor 40 functions as an input side of the current mirror circuit 20, whereas each of the second transistors 50 functions as an output side of the current mirror circuit 20. Furthermore, a current Is that is generated by each of the second transistors 50 included in the current mirror circuit 20 on the basis of the reference current Id flowing through the first transistor 40 is supplied to the SPAD elements 6a included in the pixel array unit 6. In a description below, this type of current Is is also referred to as a “supply current Is”.

As described above, the constant current source 10, the current mirror circuit 20, and the gate length adjusting unit 9 function as the current generation circuit that generates a current to be supplied to the SPAD elements 6a.

As illustrated in FIG. 5, the second transistors 50 are connected to the respective SPAD elements 6a. Namely, the pulse output unit 7 is provided with the second transistors 50, the number of which is the same as that of the SPAD elements 6a included in the pixel array unit 6.

Each of the inverters 30 outputs a signal S1 that is a pulse signal on the basis of the cathode voltage Vc of the associated SPAD elements 6a. An input terminal of each of the inverters 30 is connected between the drain of the associated second transistors 50 and the cathode of the associated SPAD elements 6a. Furthermore, an output terminal of each of the inverters 30 is connected to the control unit 8. Furthermore, an anode of each of the SPAD elements 6a is grounded.

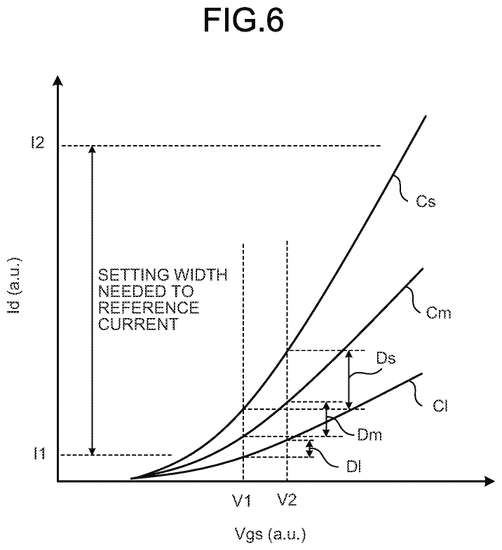

FIG. 6 is a diagram illustrating a relationship between the gate voltage Vgs and the reference current Id in the pulse output unit 7 according to the embodiment of the present disclosure. Furthermore, FIG. 6 illustrates a curved line Cs in a case in which the gate length of the first transistor 40 and the gate length of each of the second transistors 50 are in a short state, a curved line Cm in a case in which these gate lengths are in a medium state, and a curved line Cl in a case in which these gate lengths are in a long state.

As illustrated in FIG. 6, a relatively wide range (for example, from a current I1 to a current I2) is needed for the setting width of the reference current Id that is changed when a temperature around the ranging apparatus 1 is changed, when an external power supply is changed, or the like.

Furthermore, the setting width that is needed for the reference current Id is not able to cover all if the gate length is in a long state (corresponding to the curved line Cl) or in a medium state (corresponding to the curved line Cm). Namely, in order to cover all of the range of the setting width after having fixed the gate length to a single value, the gate length needs to be in a short state (corresponding to the curved line Cs).

In contrast, in the pulse output unit 7 illustrated in FIG. 5, in a case in which a photon is incident on the SPAD element s6a and the drain voltage of the second transistors 50 accordingly fluctuate, the fluctuation of the drain voltage propagates to the gate wiring 11 and thus the gate voltage Vgs fluctuates.

For example, if the gate voltage Vgs fluctuates between the voltage V1 and the voltage V2 illustrated in FIG. 6, and if the gate length is in a short state, the reference current Id varies between variation width Ds.

Furthermore, as illustrated in FIG. 6, the variation width Ds in a case in which the gate length is in a short state is greater than the variation width Dm in a case in which the gate length is in a medium state or the variation width Dl in a case in which the gate length is in a long state.

Namely, in a case in which a photon is incident on the SPAD elements 6a and the drain voltage of the second transistors 50 accordingly fluctuate, if the gate length is in a short state, the reference current Id is widely varies.

Furthermore, in the current mirror circuit 20 included in the pulse output unit 7, a value of the supply current Is that is supplied from each of the second transistors 50 is determined on the basis of the reference current Id; therefore, the supply current Is also widely varies because the reference current Id widely varies.

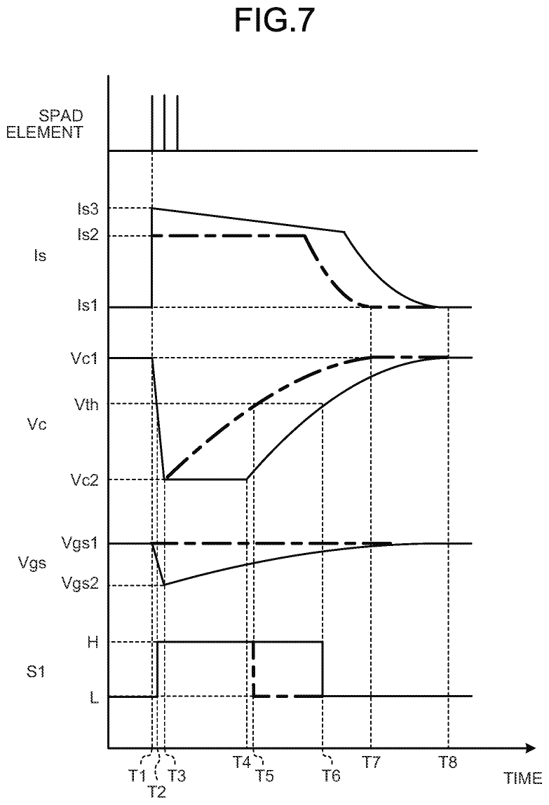

FIG. 7 is a diagram illustrating, by using a timing chart, an operation of the pulse output unit 7 in a reference example of the present disclosure, and illustrates an operation of the pulse output unit 7 in a case in which the gate length is fixed to a short state. Furthermore, in FIG. 7, in order to facilitate understanding, in addition to the reference example indicated by the solid line, an ideal case in which variations do not occur in the gate voltage Vgs is also illustrated by alternate long and short dash lines.

In the initial state, a voltage Vc1 of a reverse bias is applied to each of the SPAD elements 6a up to a state just before the occurrence of avalanche amplification referred to as a Geiger mode. Namely, in the initial state, the cathode voltage Vc of each of the SPAD elements 6a becomes the voltage Vc1.

Then, each of the inverters 30 receives an input of the voltage Vc1 that is greater than or equal to a threshold voltage Vth, so that each of the inverters 30 outputs, in the initial state, the signal S1 that is a low level. Moreover, in the initial state, the gate voltage Vgs of each of the first transistor 40 and the second transistors 50 is a voltage Vgs1.

Furthermore, in the initial state, because avalanche amplification does not occur in the SPAD elements 6a, a current Is1 having a low current value (for example, zero (A)) is supplied from each of the second transistors 50 as the supply current Is.

In the ranging apparatus 1 that is in the initial state described above, if a single photon is incident on each of the SPAD elements 6a at time T1, breakdown occurs in the SPAD elements 6a. Consequently, the cathode voltage Vc of each of the SPAD elements 6a is abruptly decreased and the supply current Is is abruptly increased.

Then, if the cathode voltage Vc becomes smaller than the threshold voltage Vth at time T2, each of the inverters 30 outputs the signal S1 that is a high level. Furthermore, the cathode voltage Vc stops falling at a voltage Vc2 because the avalanche amplification occurring in the SPAD elements 6a is stopped at time T3.

Here, in an ideal case in which variations do not occur in the gate voltage Vgs, the gate voltage Vgs maintains the voltage Vgs1 after the time T1. Consequently, after the time T1, a current Is2 that is an ideal value is stably supplied as the supply current Is to the SPAD elements 6a from the respective second transistors 50.

Consequently, the cathode voltage Vc of each of the SPAD elements 6a that stops falling at the time T3 starts to rise at the time T3 (what is called a quenching operation) caused by the SPAD elements 6a to be charged again via the respective second transistors 50.

Then, at time T5 at which the cathode voltage Vc becomes the threshold voltage Vth or more, each of the inverters 30 outputs the signal S1 that is the low level. At the end, the SPAD elements 6a return to the voltage Vc1 in the initial state at time T7, and then, the SPAD elements 6a and the pulse output unit 7 return to the initial state.

In this way, in an ideal case in which variations do not occur in the gate voltage Vgs, the pulse output unit 7 outputs the signal S1 having the pulse width between the time T2 and the time T5.

However, in practice, in a case, for example, in which a plurality of photons are incident on the SPAD elements 6a from the time T1 over a short period of time, the drain voltage of each of the second transistors 50 widely fluctuates.

Then, if the fluctuations in the drain voltage is propagated to the gate wiring 11 via the parasitic capacity of the second transistors 50, the gate voltage Vgs widely fluctuates. For example, in the example illustrated in FIG. 7, the gate voltage Vgs fluctuates from the voltage Vgs1 to a voltage Vgs2.

Furthermore, due to the fluctuations in the gate voltage Vgs, the value of the supply current Is from each of the second transistors 50 becomes a current Is3 that is greater than the ideal current Is2. Namely, if the gate length is fixed to the short state, the supply current Is that is supplied to each of the SPAD elements 6a is greatly increased as compared to the ideal case.

Consequently, the SPAD elements 6a are less subjected to quenching, so that the cathode voltage Vc maintains the voltage Vc2 up to time T4, finally rise from the time T4, and returns to the voltage Vc1 that is the initial state at time T8 that is later than the time T7 described above. Namely, if the gate length is fixed to the short state, the dead time of the SPAD elements 6a becomes very large.

As described above, if the gate length of the first transistor 40 and the gate length of each of the second transistors 50 are fixed to the short state, the dead time of each of the SPAD elements 6a widely varies due to the occurrence of variations in the gate voltage Vgs.

Furthermore, the time at which the cathode voltage Vc is greater than or equal to the threshold voltage Vth is delayed as compared to an ideal case (time T6). Therefore, if the gate length is fixed to the short state, the signal S1 that is output from the pulse output unit 7 have pulse width (from the time T2 to the time T6) that is extremely greater than that in an ideal case.

In this way, in the reference example, the dead time of each of the SPAD elements 6a and the pulse width of the signal S1 greatly vary, resulting in a decrease in the dynamic range of the ranging apparatus 1. Furthermore, the variations in the dead time and the pulse width of the signal S1 also occurs in a case in which only a single photon is incident on each of the SPAD elements 6a.

Thus, in the embodiment, the problem described above is solved by controlling the first transistor 40 and each of the second transistors 50 by the gate length adjusting unit 9.

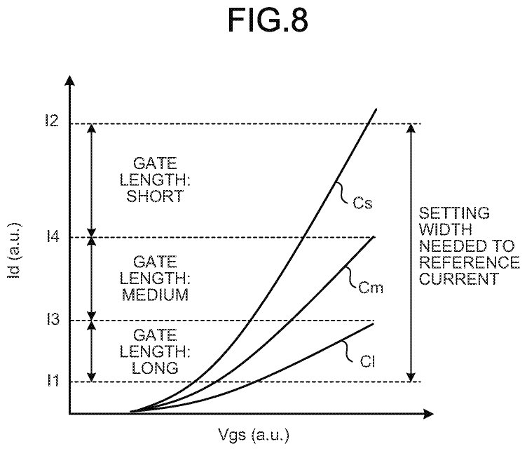

FIG. 8 is a diagram illustrating an adjusting process performed by the gate length adjusting unit 9 according to the embodiment of the present disclosure, and illustrates the curved line Cs (corresponding to the short state), the curved line Cm (corresponding to the medium state), and the curved line Cl (corresponding to the long state), which are the same as the curved lines illustrated in the graph in FIG. 6.

As illustrated in FIG. 8, from among the setting widths needed for the reference current Id, if the reference current Id is set in a range in which the gate length is able to be covered in the long state, the gate length adjusting unit 9 adjusts the gate length of the first transistor 40 and the gate length of each of the second transistors 50 to be in the long state.

For example, if the reference current Id is set in the range between the current I1 and the current I3 that is the range in which the gate length is able to be covered in the long state, the gate length adjusting unit 9 adjusts the gate length of the first transistor 40 and the gate length of each of the second transistors 50 to be in the long state.

Furthermore, from among the setting widths needed for the reference current Id, if the reference current Id is set in the range in which the gate length is able to be covered in the medium state but is not able to be covered in the long state, the gate length adjusting unit 9 adjusts the gate length of the first transistor 40 and the gate length of each of the second transistors 50 to be in the medium state.

For example, if the reference current Id is set in the range from the current I3 to the current I4 that is in the range in which the gate length is able to be covered in the medium state but is not able to be in the long state, the gate length adjusting unit 9 adjusts the gate length of the first transistor 40 and the gate length of each of the second transistors 50 to be in the medium state.

Furthermore, from among the setting widths needed for the reference current Id, if the reference current Id is set in the range in which the gate length is able to be covered in only the short state, the gate length adjusting unit 9 adjusts the gate length of the first transistor 40 and the gate length of each of the second transistors 50 to be in the short state.

For example, if the reference current Id is set in the range from the current I4 to the current I2 in which the gate length is able to be covered in only the short state, the gate length adjusting unit 9 adjusts the gate length of the first transistor 40 and the gate length of each of the second transistors 50 to be in the short state.

Consequently, for example, if the reference current Id is set in the range in which the gate length is able to be covered in the long state, the gate length of the first transistor 40 and the gate length of each of the second transistors 50 are able to be set in the long state.

Furthermore, if the reference current Id is set in the range in which the gate length is able to be covered in the long state but is not able to be covered in the medium state, the gate length of the first transistor 40 and the gate length of each of the second transistors 50 are able to be set in the medium state.

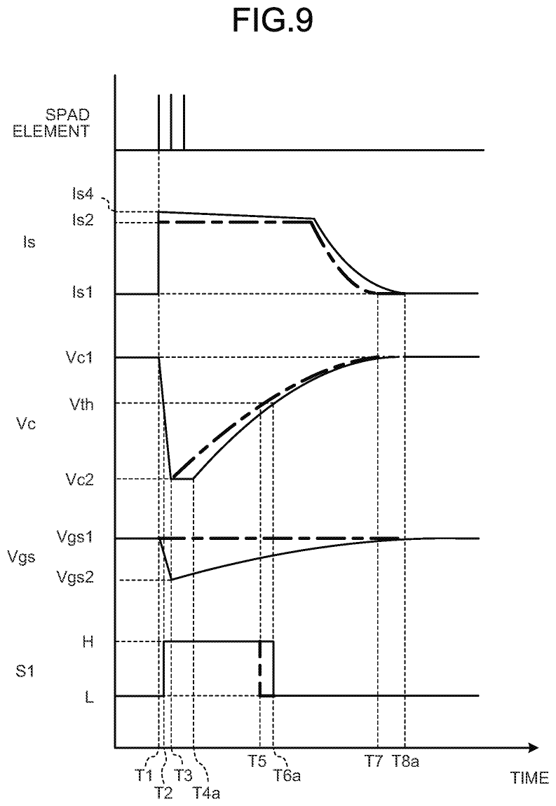

Namely, in the embodiment, it is possible to lengthen the gate length of the first transistor 40 and the gate length of each of the second transistors 50 to a maximum extent. Consequently, even if variations occur in the gate voltage Vgs, it is possible to reduce the variations in the reference current Id. The effects of reducing the variations in the reference current Id will be described with reference to FIG. 9.

FIG. 9 is a diagram illustrating, by using a timing chart, an operation of the pulse output unit 7 according to the embodiment of the present disclosure, and illustrates an operation of the pulse output unit 7 performed in a case in which the gate length of the first transistor 40 and the gate length of each of the second transistors 50 are adjusted to be in the long state. Furthermore, similarly to FIG. 7, in also FIG. 9, an ideal case in which variations do not occur in the gate voltage Vgs is illustrated by alternate long and short dash lines.

In the initial state, the voltage Vc1 of the reverse bias is applied to each of the SPAD elements 6a up to a state just before the occurrence of avalanche amplification referred to as the Geiger mode. Namely, in the initial state, the cathode voltage Vc of each of the SPAD elements 6a becomes the voltage Vc1.

Then, each of the inverter 30 receives an input of the voltage Vc1 that is greater than or equal to the threshold voltage Vth, so that, in the initial state, each of the inverters 30 outputs the signal S1 that is a low level. Furthermore, in the initial state, the gate voltage Vgs of each of the first transistor 40 and the second transistors 50 is the voltage Vgs1.

Furthermore, in the initial state, because avalanche amplification does not occur in each of the SPAD elements 6a, the current Is1 having a low current value (for example, zero (A)) is supplied from each of the second transistors 50 as the supply current Is.

In the ranging apparatus 1 that is in the initial state, if a single photon is incident on each of the SPAD elements 6a at the time T1, breakdown occurs in the SPAD elements 6a. Consequently, the cathode voltage Vc of each of the SPAD elements 6a is abruptly decreased and the supply current Is is abruptly increased.

Then, if the cathode voltage Vc becomes smaller than the threshold voltage Vth at the time T2, each of the inverters 30 outputs the signal S1 that is a high level. Furthermore, the cathode voltage Vc stops falling at a voltage Vc2 because the avalanche amplification occurring in each of the SPAD elements 6a is stopped at the time T3.

In contrast, in the embodiment, similarly to the reference example, in a case, for example, a plurality of photons are incident on each of the SPAD elements 6a from the time T1 over a short period of time, the drain voltage of each of the second transistors 50 widely fluctuates.

Then, if the fluctuations in the drain voltage is propagated to the gate wiring 11 via the parasitic capacity of each of the second transistors 50, the gate voltage Vgs widely fluctuates from the voltage Vgs1 to the voltage Vgs2.

However, in the embodiment, the gate length of the first transistor 40 and the gate length of each of the second transistors 50 are adjusted to be in the long state. Consequently, even if the gate voltage Vgs fluctuates to the voltage Vgs2, it is possible to reduce the fluctuations in the reference current Id and it is thus possible to reduce the fluctuations in the supply current Is.

For example, as illustrated in FIG. 9, the value of the supply current Is received from each of the second transistors 50 is a current Is4 that is smaller than the current Is3, which is indicated in the reference example, due to the fluctuations in the gate voltage Vgs. Namely, by adjusting the gate length on the basis of the reference current Id, it is possible to reduce an increase rate of the supply current Is that is supplied to each of the SPAD elements 6a.

Consequently, each of the SPAD elements 6a is easily subjected to quenching as compared to the reference example, so that the cathode voltage Vc maintains the voltage Vc2 up to time T4a that is before the time T4 described in the reference example, and then, rises from the time T4a. Then, the cathode voltage Vc returns to the voltage Vc1 that is in the initial state at time T8a that is before time T8 described in the reference example.

Namely, by adjusting the gate length on the basis of the reference current Id, it is possible to reduce the variations in the dead time of each of the SPAD elements 6a.

Furthermore, the time at which the cathode voltage Vc is greater than the threshold voltage Vth also reaches earlier than that described in the reference example (time T6a). Accordingly, by adjusting the gate length on the basis of the reference current Id, the signal S1 that is output from the pulse output unit 7 has the pulse width (from the time T2 to the time T6a) that is closer to an ideal case as compared in the reference example.

As described above, in the embodiment, by adjusting the gate length on the basis of the reference current Id, it is possible to reduce the variations in the dead time of each of the SPAD elements 6a and the pulse width of the signal S1. Therefore, according to the embodiment, it is possible to expand the dynamic range of the ranging apparatus 1.

Furthermore, in the embodiment, even in a case in which only a single photon is incident on each of the SPAD elements 6a, it is possible to reduce the variations in the dead time of each of the SPAD elements 6a and the pulse width in the signal S1.

Furthermore, in the embodiment, it is preferable to configure the first transistor 40 by using the P-type transistors 41 to 43, which are connected in series, and the bypass switches 44 and 45, which are transistors having the minimum size.

Consequently, as compared to a case in which a plurality of P-type transistors each having a needed gate length are arranged in parallel, it is possible to reduce an element area of the first transistor 40. Therefore, according to the embodiment, it is possible to arrange the first transistor 40 in the logic chip 3b without any difficulty.

Furthermore, in the embodiment, the circuit configuration of the first transistor 40 is not limited to the example illustrated in FIG. 5, and, for example, a plurality of P-type transistors each having a gate length may also be arranged in parallel.

Furthermore, in the embodiment, it is preferable to configure each of the second transistors 50 by using the P-type transistors 51 to 53, which are connected in series, and the bypass switches 54 and 55, which are transistors having the minimum size.

Consequently, as compared to a case in which a plurality of P-type transistors each having a needed gate length are arranged in parallel, it is possible to reduce an element area of each of the second transistors 50. Therefore, according to the embodiment, even in a case in which a large number of the SPAD elements 6a are provided on the light receiving chip 3a, it is possible to arrange a needed number of the second transistors 50 in the logic chip 3b without any difficulty.

Furthermore, in the embodiment, the circuit configuration of each of the second transistors 50 is not limited to the example illustrated in FIG. 5, and, for example, a plurality of P-type transistors each having a gate length may also be arranged in parallel.

Furthermore, in the embodiment, it is preferable to arrange a plurality of the second transistors 50 in a single piece of the current mirror circuit 20. Consequently, it is possible to supply, using a single piece of the constant current source 10, the supply current Is with a value that is substantially the same as that of each of the plurality of the SPAD elements 6a.

Furthermore, if a plurality of the second transistors 50 are arranged in the single current mirror circuit 20, the variations occur in the gate voltage Vgs as described above even when a plurality of photons are incident on the plurality of the SPAD elements 6a that are connected to the respective second transistors 50.

However, in the embodiment, by controlling the gate length of each of the plurality of the second transistors 50 using the gate length adjusting unit 9, even in a case in which gate voltage Vgs varies, it is possible to reduce the variations in the dead time of each of the SPAD elements 6a and the pulse width of the signal S1. Furthermore, the number of the constant current sources 10 arranged in the pulse output unit 7 may also be one or may also be plural.

[Effects]

The current generation circuit according to the embodiment includes the constant current source 10, the current mirror circuit 20, and the gate length adjusting unit 9. The constant current source 10 is able to flow the reference current Id with a plurality of values. The current mirror circuit 20 is constituted by the first transistor 40 that is connected to the constant current source 10 and the second transistors 50 that are connected to the respective SPAD elements 6a. The gate length adjusting unit 9 adjusts, on the basis of the reference current Id that is set in the constant current source 10, the gate length of the first transistor 40 and the gate length of each of the second transistors 50.

Consequently, it is possible to expand the dynamic range of the ranging apparatus 1.

Furthermore, in the current generation circuit according to the embodiment, the first transistor 40 includes a plurality of transistors (the P-type transistors 41 to 43) that are connected in series and that have a common gate, and the bypass switches 44 and 45 that bypass some of the plurality of transistors. Furthermore, the bypass switches 44 and 45 are transistors having the minimum size.

Consequently, it is possible to arrange the first transistor 40 in the logic chip 3b without any difficulty.

Furthermore, in the current generation circuit according to the embodiment, each of the second transistors 50 includes a plurality of transistors (the P-type transistors 51 to 53) that are connected in series and that have a common gate, and the bypass switches 54 and 55 that bypass some of the plurality of transistors. Furthermore, the bypass switches 54 and 55 are transistors having the minimum size.

Consequently, even in a case in which a large number of the SPAD elements 6a is provided on the light receiving chip 3a, it is possible to arrange the needed number of the second transistors 50 in the logic chip 3b without any difficulty.

Furthermore, in the current generation circuit according to the embodiment, the current mirror circuit 20 includes a plurality of the second transistors 50, and the plurality of the second transistors 50 are connected to the plurality of the respective SPAD elements 6a.

Consequently, it is possible to supply the supply current Is with the value that is substantially the same as that of each of the plurality of the SPAD elements 6a by using the single constant current source 10.

Furthermore, in the current generation circuit according to the embodiment, the constant current source 10 flows the reference current Id with a plurality of values in accordance with the setting.

Consequently, in accordance with an external environment or the like, it is possible to flow the reference current Id with an optimum value.

In the above, the embodiment according to the present disclosure has been described; however, the technical scope of the present disclosure is not limited to the embodiment described above and various modifications are possible without departing from the scope of the present disclosure. Furthermore, component described in different embodiments and modifications may also be used in any appropriate combination.

For example, in the embodiment, a description has been given of a case in which the gate length of the first transistor 40 and the gate length of each of the second transistors 50 are controlled at three levels (in the short state, in the medium state, and in the long state); however, control of the gate length is not limited to these three levels.

For example, the gate length of the first transistor 40 and the gate length of each of the second transistors 50 may also be controlled at two levels or may also be controlled at four levels. In this case, the number of P-type transistors and the number of bypass switches provided in the first transistor 40 and the second transistors 50 may also appropriately be increased or decreased.

Furthermore, the effects described in this application are only an example and are not limited thereto, and furthermore, other effects may also be obtained.

Furthermore, the present technology can also be configured as follows.
(1) A current generation circuit comprising:

a constant current source that is able to flow a reference current with a plurality of values;

a current mirror circuit that is constituted by a first transistor that is connected to the constant current source and a second transistor that is connected to a single photon avalanche diode (SPAD) element; and

a gate length adjusting unit that adjusts, on the basis of the reference current that is set in the constant current source, a gate length of the first transistor and a gate length of the second transistor.
(2) The current generation circuit according to (1), wherein

the first transistor includes
a plurality of transistors that are connected in series and that have a common gate, and
a bypass switch that bypasses some of the plurality of transistors, and

the bypass switch is a transistor having the minimum size.
(3) The current generation circuit according to (1) or (2), wherein

the second transistor includes
a plurality of transistors that are connected in series and that have a common gate, and
a bypass switch that bypasses some of the plurality of transistors, and

the bypass switch is a transistor having the minimum size.
(4) The current generation circuit according to any one of (1) to (3), wherein

the current mirror circuit includes a plurality of the second transistors, and

the plurality of the second transistors are connected to a plurality of the respective SPAD elements.
(5) The current generation circuit according to any one of (1) to (4), wherein

the constant current source flows, in accordance with the setting, the reference current with the plurality of values.
(6) A ranging system comprising:

a light source that irradiates an object to be measured with light;

a SPAD element that outputs a signal when light reflected from the object to be measured is received; and

a current generation circuit that includes
a constant current source that is able to flow a reference current with a plurality of values,
a current mirror circuit that is constituted by a first transistor that is connected to the constant current source and a second transistor that is connected to the SPAD element, and
a gate length adjusting unit that adjusts, on the basis of the reference current that is set in the constant current source, a gate length of the first transistor and a gate length of the second transistor.
(7) The ranging system according to (6), wherein

the first transistor includes
a plurality of transistors that are connected in series and that have a common gate, and
a bypass switch that bypasses some of the plurality of transistors, and

the bypass switch is a transistor having the minimum size.
(8) The ranging system according to (6) or (7)

the second transistor includes
a plurality of transistors that are connected in series and that have a common gate, and
   a bypass switch that bypasses some of the plurality of transistors, and

the bypass switch is a transistor having the minimum size.
(9) The ranging system according to any one of (6) to (8)

the current mirror circuit includes a plurality of the second transistors, and

the plurality of the second transistors are connected to a plurality of the respective SPAD elements.
(10) The ranging system according to any one of (6) to (9), wherein the constant current source flows, in accordance with the setting, the reference current with a plurality of values.

### Reference Signs List

1 ranging apparatus (an example of ranging system)
2 light source unit
3 light receiving unit
6a SPAD elements
7 pulse output unit
8 control unit
9 gate length adjusting unit
10 constant current source
20 current mirror circuit
30 inverters
40 first transistor
41 to 43 P-type transistor
44, 45 bypass switch
50 second transistors
51 to 53 P-type transistor
54, 55 bypass switch
Id reference current
Is supply current

1. A current generation circuit comprising:
a constant current source that is able to flow a reference current with a plurality of values;
a current mirror circuit that is constituted by a first transistor that is connected to the constant current source and a second transistor that is connected to a single photon avalanche diode (SPAD) element; and
a gate length adjusting unit that adjusts, on the basis of the reference current that is set in the constant current source, a gate length of the first transistor and a gate length of the second transistor.

2. The current generation circuit according to claim 1, wherein
the first transistor includes
a plurality of transistors that are connected in series and that have a common gate, and
a bypass switch that bypasses some of the plurality of transistors, and
the bypass switch is a transistor having the minimum size.

3. The current generation circuit according to claim 1, wherein
the second transistor includes
a plurality of transistors that are connected in series and that have a common gate, and
a bypass switch that bypasses some of the plurality of transistors, and
the bypass switch is a transistor having the minimum size.

4. The current generation circuit according to claim 1, wherein
the current mirror circuit includes a plurality of the second transistors, and
the plurality of the second transistors are connected to a plurality of the respective SPAD elements.

5. The current generation circuit according to claim 1, wherein
the constant current source flows, in accordance with the setting, the reference current with the plurality of values.

6. A ranging system comprising:
a light source that irradiates an object to be measured with light;
a SPAD element that outputs a signal when light reflected from the object to be measured is received; and
a current generation circuit that includes
a constant current source that is able to flow a reference current with a plurality of values,
a current mirror circuit that is constituted by a first transistor that is connected to the constant current source and a second transistor that is connected to the SPAD element, and
a gate length adjusting unit that adjusts, on the basis of the reference current that is set in the constant current source, a gate length of the first transistor and a gate length of the second transistor.
